(19) United States
(12) Patent Application Publication
(10) Pub. No.: US 2013/0171348 A1
(43) Pub. Date: Jul. 4, 2013

(54) THIN FILM DEPOSITION APPARATUS AND METHOD FOR USING THE SAME

(71) Applicants: CHIEN-CHUNG FANG, New Taipei City (TW); NIEN-TZU LIU, Taipei City (TW)

(72) Inventors: CHIEN-CHUNG FANG, New Taipei City (TW); NIEN-TZU LIU, Taipei City (TW)

(73) Assignee: PINECONE MATERIAL INC., Grand Cayman (KY)

(21) Appl. No.: 13/527,893

(22) Filed: Jun. 20, 2012

(30) Foreign Application Priority Data
Dec. 28, 2011 (TW) 100149252

(51) Int. Cl. C23C 16/02; C23C 16/44; C23C 16/56

(52) U.S. Cl. 427/248.1; 118/66; 118/725; 427/398.1; 427/314

(57) ABSTRACT

A thin film deposition apparatus and a using method thereof are disclosed. The apparatus includes a preheating chamber, a reacting chamber, a cooling chamber, and at least one transmission module. The preheating chamber is configured for preheating the substrate. The reacting chamber is configured for receiving the substrate being preheated and transferred from the preheating chamber, heating the substrate to a working temperature, depositing a thin film on the substrate under the working temperature, and cooling the substrate being deposited to a temperature lower than the working temperature. The cooling chamber is configured for receiving the substrate being deposited and transferred from the reacting chamber and further cooling the substrate. The transmission module is configured for transferring the substrate between the preheating chamber, the reacting chamber, and the cooling chamber.

### CROSS-REFERENCE TO RELATED APPLICATIONS

This application is based upon and claims the benefit of priority from the prior Taiwanese Patent Application No. 100149252, filed Dec. 28, 2011, the entire contents of which are incorporated herein by reference.

### BACKGROUND

1. Field of the Invention

The present invention generally relates to semiconductor process and equipment, and more particularly to a thin film deposition apparatus and method for using the same.

2. Description of the Related Art

Thin film deposition techniques are adapted for surface treatment for various kinds of articles or components, such as semiconductor components. Thin film deposition techniques are used for depositing a thin film or a plurality of thin films of homogeneous or heterogeneous materials onto a wafer substrate or a substrate made of a metal, a cemented carbide, or ceramics. Thin film deposition techniques fall into two broad categories, depending on whether the process is primarily chemical or physical, one is physical vapor deposition (PVD) and the other is chemical vapor deposition (CVD).

The structure of the deposited film may be single crystal, polycrystalline, or amorphous structure according to the deposition process and parameters thereof. Deposition of a single crystal structured (crystalline) thin film is particularly important in the integrated circuit manufacturing process, known as epitaxy. The main advantage of the epitaxial thin film is that donor or acceptor can be directly doped during the deposition process, so the dopant profile of the thin film can be precisely controlled and the thin film does not contain impurities such as oxygen and carbon.

The principle of metal-organic chemical vapor deposition (MOCVD) is using carrier gas to carry the gas reactants or precursors into a cavity equipped with a wafer. A susceptor under the bottom of the wafer is heated by, for example, high frequency induction or resistance. The wafer and gas around the wafer is heated to a high temperature to trigger a chemical reaction between one or more gases and to convert normally gaseous reactants into a solid resultant that is deposited on the surface of the wafer.

MOCVD is a chemical reaction under high temperature conditions. When an epitaxial process is complete, the wafer can only be moved out from the MOCVD chamber until the internal temperature of the MOCVD chamber is cooled to 150° C. or even a lower temperature so as to avoid deformation or rupture of the susceptor and the wafer due to thermo shock. However, since this cooling typically takes a long time, the cost of the epitaxy process is increased.

### BRIEF SUMMARY

The present invention relates to a thin film deposition apparatus, which can decrease interval time between deposition processes for each substrate, save energy, and improve work efficiency.

The present invention also relates to a method of using the thin film deposition apparatus.

To achieve the above advantages, a thin film deposition apparatus, for depositing a thin film on a substrate, is provided. The apparatus includes a preheating chamber, a reacting chamber, a cooling chamber, and at least one transmission module. The preheating chamber is configured for preheating the substrate. The reacting chamber is configured for receiving the substrate being preheated and transferred from the preheating chamber, heating the substrate to a working temperature, depositing a thin film on the substrate under the working temperature, and cooling the substrate being deposited to a temperature lower than the working temperature. The cooling chamber is configured for receiving the substrate being deposited and transferred from the reacting chamber and further cooling the substrate. The transmission module is configured for transferring the substrate between the preheating chamber, the reacting chamber, and the cooling chamber.

In an embodiment of the present invention, the at least one transmission module includes a buffer chamber. The buffer chamber is connected to the preheating chamber, the reacting chamber, and the cooling chamber, respectively, by a gate. The buffer chamber includes at least one mechanical arm disposed therein The mechanical arm is configured for transferring the substrate between the preheating chamber and the reacting chamber before the substrate is deposited, and transferring the substrate between the reacting chamber and the cooling chamber after the substrate has been deposited.

In an embodiment of the present invention, the apparatus further includes gas supply equipment. The gas supply equipment is connected to the preheating chamber, the buffer chamber, and the cooling chamber to supply at least one kind of inert gas to the preheating chamber, the buffer chamber, and the cooling chamber.

In an embodiment of the present invention, the buffer chamber and any of the other chambers connected thereto maintain the same gas atmosphere when the gate connected therebetween is open.

In an embodiment of the present invention, the preheating chamber, the buffer chamber and the cooling chamber each has at least one independent heater.

In an embodiment of the present invention, the buffer chamber and any of the other chambers connected thereto maintain the same temperature when the gate connected therebetween is open.

In an embodiment of the present invention, the transmission module includes: a first buffer chamber and a second buffer chamber. The first buffer chamber is connected to the preheating chamber and the reacting chamber, respectively, by a gate. The first buffer chamber includes a mechanical arm disposed therein that is configured for transferring the substrate between the preheating chamber and the reacting chamber before the substrate is deposited. The second buffer chamber is connected to the reacting chamber and the cooling chamber, respectively, by a gate. The second buffer chamber includes a second mechanical arm disposed therein that is configured for transferring the substrate between the reacting chamber and the cooling chamber after the substrate has been deposited.

In an embodiment of the present invention, the apparatus further includes gas supply equipment. The gas supply equipment is connected to the preheating chamber, the first buffer chamber, the second buffer chamber, and the cooling chamber to supply at least one kind of inert gas to the preheating chamber, the buffer chamber, the second buffer chamber, and the cooling chamber.

In an embodiment of the present invention, the first or the second buffer chamber and chambers connected thereto maintain the same gas atmosphere when the gate connected therebetween is open, and the second buffer chamber and the chambers connected thereto maintain the same gas atmosphere when the gate connected therebetween is open.

In an embodiment of the present invention, the first buffer chamber and the chambers connected thereto maintain the same temperature when the gate connected therebetween is open, and the second buffer chamber and the chambers connected thereto maintain the same temperature when the gate connected therebetween is open.

In an embodiment of the present invention, the preheating chamber and the cooling chamber are parallel set or stacked.

In an embodiment of the present invention, the thin film deposition apparatus is a metal-organic chemical vapor deposition apparatus and performing a metal-organic chemical vapor deposition process.

To achieve the above advantages, another thin film deposition apparatus for depositing a thin film on a substrate is provided. The thin film deposition apparatus includes a preheating chamber, a reacting chamber, a cooling chamber, and at least one transmission module. The preheating chamber is configured for preheating the substrate to a first temperature. The reacting chamber is configured for receiving the substrate being preheated and transferred from the preheating chamber, heating the substrate to a working temperature, depositing a thin film on the substrate under the working temperature, and cooling the substrate that has been deposited in the reacting chamber from the working temperature to the first temperature. The cooling chamber is configured for receiving the substrate being deposited and transferred from the reacting chamber, and further cooling the substrate from the first temperature to a second temperature. The at least one transmission module is configured for transferring the substrate between the preheating chamber, the reacting chamber, and the cooling chamber.

In an embodiment of the present invention, the first temperature is from 400 to 600.

In an embodiment of the present invention, the second temperature is from room temperature to 150° C.

To achieve the above advantages, a method for using a thin film deposition apparatus is provided. The method includes steps of: depositing a thin film on the substrate in the reacting chamber and under the working temperature; after being deposited, cooling the substrate to the first temperature; adjusting the temperature in the cooling chamber and the transmission module to the first temperature; transferring the substrate from the reacting chamber to the cooling chamber by the transmission module; and cooling the substrate to the second temperature in the cooling chamber.

In an embodiment of the present invention, before the step of transferring the substrate from the reacting chamber to the cooling chamber by the transmission module, the method further includes a step of adjusting the cooling chamber, the transmission module, and the reacting chamber to the same gas atmosphere.

In an embodiment of the present invention, before the step of transferring the substrate from the preheating chamber to the reacting chamber by the transmission module, the method further includes a step of adjusting the preheating chamber, the transmission module, and the reacting chamber to the same gas atmosphere.

In the present invention, when the thin film deposition process in the reacting chamber is completed, the substrate can be moved out from the reacting chamber and put into the cooling chamber, not having to wait for the temperature of the reacting chamber to be cooled to a low temperature. During the period of cooling the substrate in the cooling chamber, another substrate being preheated to the first temperature in the preheating chamber can be transferred to the reacting chamber and deposited therein. Therefore, the interval time between deposition processes for each substrate can be saved, work efficiency can be improved, and energy also can be saved.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a schematic view of a thin film deposition apparatus in accordance with a first embodiment of the present invention.

FIG. 2 is a sectional view of the reacting chamber and the buffer chamber of the thin film deposition apparatus shown in FIG. 1.

FIG. 3 is a schematic view of a thin film deposition apparatus in accordance with a second embodiment of the present invention.

FIG. 4 is a schematic view of the preheat-cooling chamber in FIG. 3.

FIG. 5 is a schematic view of a thin film deposition apparatus in accordance with a third embodiment of the present invention.

FIG. 6 is a flow chart of a using method of the thin film deposition apparatus.

### DETAILED DESCRIPTION

Reference will now be made to the drawings to describe exemplary embodiments of the present thin film deposition apparatus and method for using the same, in detail. The following description is given by way of example, and not limitation.

A thin film deposition apparatus of the present invention is adapted for performing a semiconductor manufacturing process on a substrate. In the following exemplary embodiments, the thin film deposition apparatus is used for depositing III-Nitride on a substrate as an example. Of course, as one skilled in the art will appreciate, the thin film deposition apparatus of the present invention can also be used for other semiconductor manufacturing processes, including preheating and cooling processes.

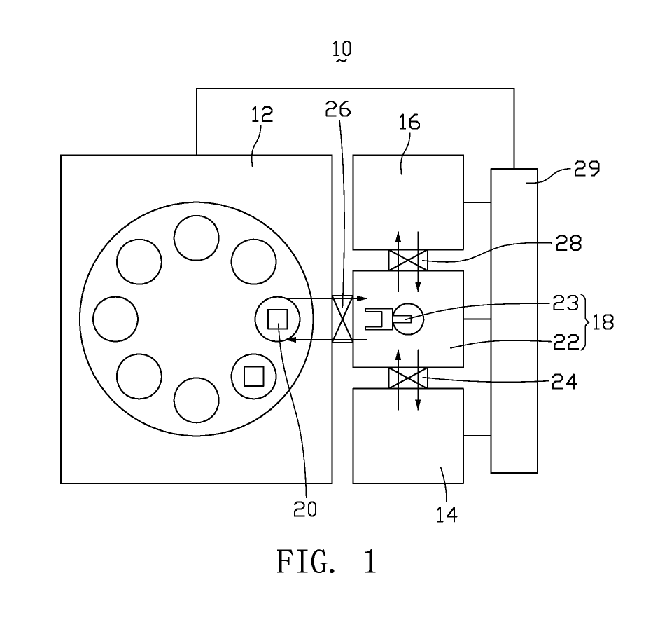

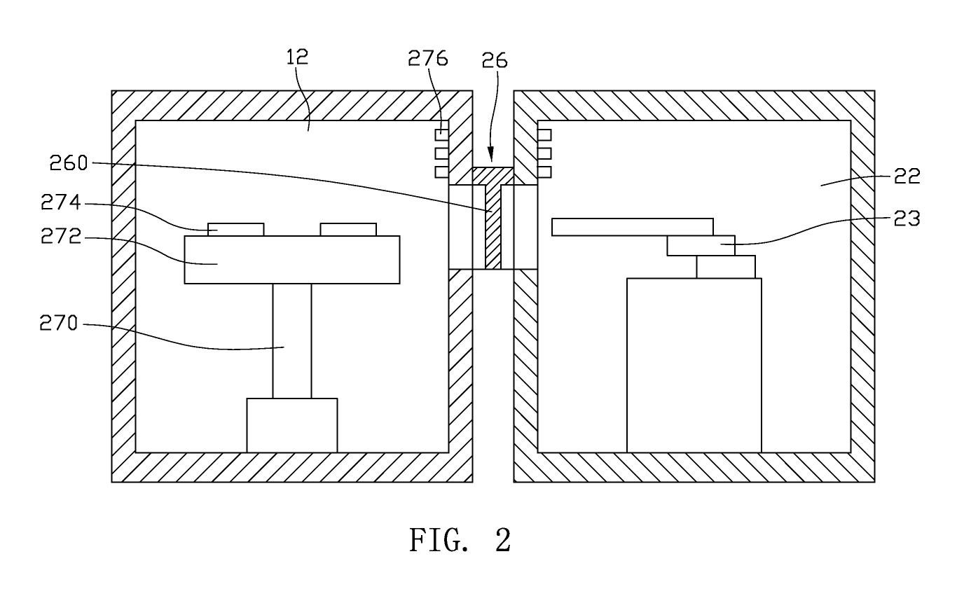

FIG. 1 is a schematic view of a thin film deposition apparatus in accordance with a first embodiment of the present invention. FIG. 2 is a sectional view of the reacting chamber and the buffer chamber of the thin film deposition apparatus shown in FIG. 1. Referring to FIGS. 1 and 2, in the first embodiment, the thin film deposition apparatus 10 includes a reacting chamber 12, a preheating chamber 14, a cooling chamber 16, and a transmission module 18. The transmission module 18 is configured for transferring a substrate 20 between the preheating chamber 14, the reacting chamber 12, and the cooling chamber 16. First, the substrate 20 is transferred to the preheating chamber 14 to be preheated. After being preheated, the substrate 20 is transferred to the reacting chamber 12 from the preheating chamber 14. Then in the reacting chamber 12, the substrate 20 is heated to a working temperature a thin film or thin films are deposited thereon. When the thin film deposition process is complete, the substrate 20 in the reacting chamber 12 is cooled. And then, the substrate 20 is transferred from the reacting chamber 12 to the cooling chamber 16 to be cooled to a lower temperature.

The preheating chamber 14 and the cooling chamber 16 can also function as a load lock chamber. Generally, the substrate is transferred into or out of a vacuum process chamber via a transfer chamber. The general function of the transfer chamber is often referred to as atmospheric/vacuum interface and the load lock chamber. The load lock chamber supplies the stage vacuum between atmospheric pressure and the pressure of the vacuum process chamber. In some systems, the load lock chamber is a transmission interface between a queuing system in the ambient pressure and the vacuum process chamber for exchanging the substrate between the atmosphere and the vacuum. Similarly, after being treated, the substrate may be transferred from the vacuum process chamber to the atmosphere via the load lock chamber. The size of the multiple openings in the vacuum process chamber and the load lock chamber is usually designed to be capable of receiving at least one dimension (i.e., width or length) of a large size substrate in order to facilitate the transfer of the substrate. These openings of the chambers are designed to be selectively open or closed by a gate, in order to facilitate the transfer of the substrate and vacuum sealing the chambers.

To be specific, in the preheating chamber 14, the substrate 20 is heated from a room temperature T0 to a first temperature T1. After being preheated, the substrate 20 is transferred from the preheating chamber 14 to the reacting chamber 12 by the transmission module 18. In the reacting chamber 12, the substrate 20 is heated from the first temperature T1 to a working temperature Tw and a thin film or thin films are deposited thereon. When the thin film deposition process is complete, the substrate 20 is cooled from the working temperature Tw to the first temperature T1 in the reacting chamber 12. Then, the substrate 20 is transferred from the reacting chamber 12 to the cooling chamber 16 by the transmission module 18 and cooled from the first temperature T1 to a second temperature T2 in the cooling chamber 16. The second temperature T2 is lower than the first temperature T1 and higher than the room temperature T0, i.e., T0 T2 T1 Tw. In the first embodiment, the first temperature T1 is in a range from 400 to 600, 500 for example. The second temperature T2 is in a range from the room temperature to 150, 100 for example. That means, after the thin film deposition process in the reacting chamber 12 is completed, the substrate 20 can be moved out from the reacting chamber 12 and put into the cooling chamber 16, not having to wait for the temperature of the reacting chamber to be cooled to a low temperature. During the period of cooling the substrate 20 in the cooling chamber 16, another substrate can be preheated to the first temperature T1 in the preheating chamber 14 and can be transferred to the reacting chamber 12 and deposited therein. Therefore, the interval time between deposition processes for each substrate can be decreased, work efficiency can be improved, and energy also can be saved.

To be more specific, in the first embodiment, the transmission module 18 includes a buffer chamber 22 and a mechanical arm 23 disposed in the buffer chamber 22. The buffer chamber 22 is connected between the preheating chamber 14 and the reacting chamber 12 and also connected between the reacting chamber 12 and the cooling chamber 16. The mechanical arm 23 is configured for transferring the substrate 20 before being deposited from the preheating chamber 14 to the reacting chamber 12, and transferring the substrate 20 after being deposited from the reacting chamber 12 to the cooling chamber 16. In other words, before the thin film deposition process, the substrate 20 is transferred from the preheating chamber 14 to the reacting chamber 12 by the mechanical arm 23. When the thin film deposition process is completed, the substrate 20 is transferred from the reacting chamber 12 to the cooling chamber 16 by the mechanical arm 23.

Referring to FIGS. 1 and 2, the thin film deposition apparatus 10 further includes a first gate 24, a second gate 26 and a third gate 28. The first gate 24 is disposed between the preheating chamber 14 and the buffer chamber 22, the second gate 26 is disposed between the reacting chamber 12 and the buffer chamber 22, and the third gate 28 is disposed between the cooling chamber 16 and the buffer chamber 22. That means, in the first embodiment, the mechanical arm 23 respectively moves in and out from the preheating chamber 14 though first gate 24, moves in and out from the reacting chamber 12 through the second gate 26, and moves in and out from the cooling chamber 16 though the third gate 28.

Referring to FIG. 2 again, in the first embodiment, the substrate 20 is disposed on a holder 274 and supported by a susceptor 272. A shaft 270 disposed under the susceptor 272 and is configured for driving the susceptor 272 to rotate. Of course, the carrying mode of the substrate 20 can be changed depending on the specific process, and is not limited by the illustrated embodiment.

In the first embodiment, the thin film deposition apparatus 10 further includes a plurality of heaters 276. The plurality of heaters 276 are respectively disposed in the preheating chamber 14, the reacting chamber 12, the cooling chamber 16 and the buffer chamber 22. Due to the visual angle, FIG. 2 only shows the heaters 276 disposed in the reacting chamber 12 and the buffer chamber 22. The preheating chamber 14, the reacting chamber 12, the cooling chamber 16, and the buffer chamber 22 are heated separately or simultaneously by the heaters 276. The heater 276 can be, but are not limited to, a tungsten heater, a ceramic heater, or a radio frequency heater. A valve 260 is provided on the second gate 26 between the reacting chamber 12 and the buffer chamber 22 for opening or closing the second gate 26. The first gate 24 and the third gate 28 can also have a similar design. Of course, the present invention is not limited for other designs. When one or more of the first gate 24, the second gate 26 and the third gate 28 is open, the buffer chamber 22 and the other chambers connected thereto maintain the same temperature. For example, when the first gate 24 is open, the preheating chamber 14 and the buffer chamber 22 maintain the same temperature. When the first gate 24 and the second gate 26 are open, the preheating chamber 14, the reacting chamber 12, and the buffer chamber 22 maintain the same temperature.

Referring to FIG. 1 again, the thin film deposition apparatus 10 further includes gas supply equipment 29 for supplying at least one kind of inert gas to the preheating chamber 14, the buffer chamber 22, and the cooling chamber 16. When one or both of the first gate 24 and the third gate 28 are open, the buffer chamber 22, the preheating chamber 14, or the cooling chamber 16 connected thereto maintain the same gas atmosphere. Of course, theses chambers can also be naturally cooled.

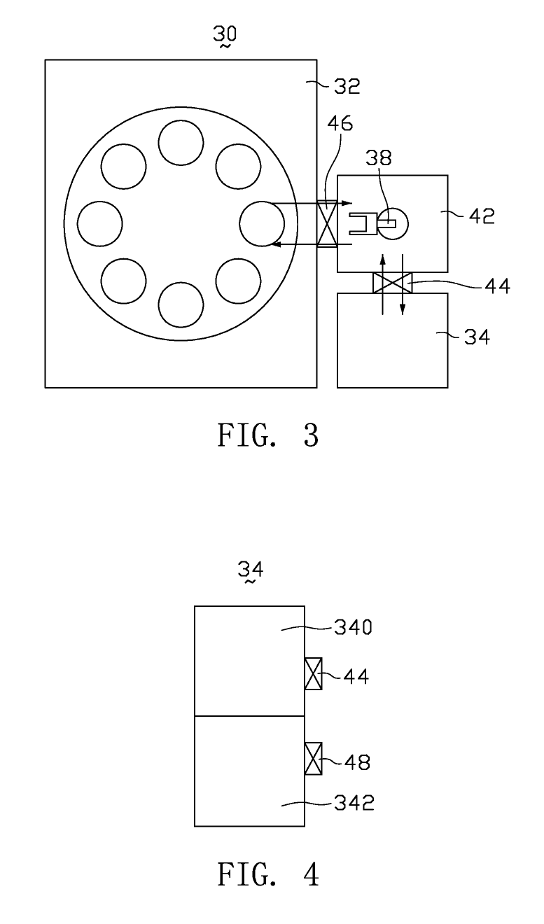

FIG. 3 is a schematic view of a thin film deposition apparatus in accordance with a second embodiment of the present invention. FIG. 4 is a schematic view of the preheat-cooling chamber in FIG. 3. In the second embodiment, the thin film deposition apparatus 30 includes a reacting chamber 32, a buffer chamber 42, and a mechanical arm 38 disposed in the buffer chamber 42. The difference between the thin film deposition apparatus 30 and the thin film deposition apparatus 10 in the first embodiment is that the thin film deposition apparatus 30 includes a preheat-cooling chamber 34. That is, the preheating chamber 14 and the cooling chamber 16 in the first embodiment are stacked to one preheat-cooling chamber 34 in the second embodiment to reduce the space occupied by thin film deposition apparatus 30.

In the second embodiment, the preheat-cooling chamber 34 is divided into upper chamber 340 and lower chamber 342 for preheating and cooling the substrate respectively. Referring to FIGS. 3 and 4, the thin film deposition apparatus 30 further includes a first gate 44, a second gate 46 and a third gate 48. The buffer chamber 42 is connected to the upper chamber 340 through the first gate 44, connected to the reacting chamber 32 through the second gate 46, and connected to the lower chamber 342 through the third gate 48. The preheat-cooling chamber 34 also can be divided into two chambers next to each other (facing to any side, not up or down), not limited by the illustrated embodiment. In the second embodiment, the upper chamber 340 is used as a preheating chamber and the lower chamber 342 is used as a cooling chamber. The substrate is preheated in the upper chamber 340 from room temperature T0 to the first temperature T1. After being preheated, the substrate is transferred to the reacting chamber 32 by the mechanical arm 38. Then the substrate is heated from the first temperature T1 to the working temperature Tw in the reacting chamber 32 and is deposited under the working temperature Tw. After being deposited, the substrate is transferred to the lower chamber 342. In the lower chamber 342, the substrate is cooled to the second temperature T2.

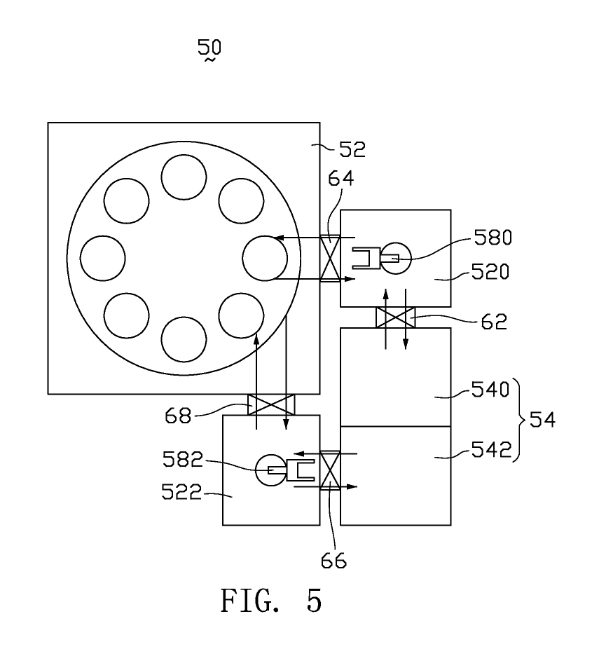

FIG. 5 is a schematic view of a thin film deposition apparatus in accordance with a third embodiment of the present invention. In the third embodiment, the thin film deposition apparatus 50 includes a reacting chamber 52 and a preheat-cooling chamber 54. The difference between the thin film deposition apparatus 50 and the thin film deposition apparatus 30 in the second embodiment is that, in the third embodiment, the mechanical arm includes a first mechanical arm 580 and a second mechanical arm 582, and the buffer chamber includes a first buffer chamber 520 and a second buffer chamber 522. The first buffer chamber 520 is connected between the preheat-cooling chamber 54 and the reacting chamber 52, and the first mechanical arm 580 is disposed in the first buffer chamber 520. The second buffer chamber 522 is connected between the reacting chamber 52 and the preheat-cooling chamber 54, and the second mechanical arm 582 is disposed in the second buffer chamber 522.

The thin film deposition apparatus 50 further includes a first gate 62, a second gate 64, a third gate 68, and a fourth gate 66. The preheat-cooling chamber 54 includes a first chamber 540 and a second chamber 542. The first chamber 540 and the second chamber 542 are parallel set or stacked. The first buffer chamber 520 is connected to the first chamber 540 by the first gate 62, and connected to the reacting chamber 52 by the second gate 64. The second buffer chamber 522 is connected to the reacting chamber 52 by the third gate 68, and connected to the second chamber 542 by the fourth gate 66. In the third embodiment, the first chamber 540 is used as a preheating chamber, and the second chamber 542 is used as a cooling chamber. The first buffer chamber 520 is connected to the first chamber 540 by the first gate 62 and connected to the reacting chamber 52 by the second gate 64. Before being deposited, the substrate is transferred between the first chamber 540 and the reacting chamber 52 by the first mechanical arm 580. The second buffer chamber 522 is connected to the reacting chamber 52 by the third gate 68 and connected to the second chamber 542 by the fourth gate 66. After being deposited, the substrate is transferred between the reacting chamber 52 and the second chamber 542 by the second mechanical arm 582.

To be more specific, the substrate in the first chamber 540 is heated from room temperature T0 to the first temperature T1. The substrate is transferred to the reacting chamber 52 by the first mechanical arm 580 and heated from the first temperature T1 to the working temperature Tw in the reacting chamber 52. Then the substrate is deposited under the working temperature Tw in the reacting chamber 52. After being deposited, the substrate is transferred to the second chamber 542 by the second mechanical arm 582 and cooled the second temperature T2 in the second chamber 542. In the third embodiment, after being deposited, the substrate is moved out from the reacting chamber 52 by the first mechanical arm 580, at the same time, the substrate before being deposited is moved in the reacting chamber 52 by the second mechanical arm 582, thereby saving time of process.

It is can be understood that, in alternative embodiments, the first chamber 540 and the second chamber 542 can be stacked like in the second embodiment. The first mechanical arm 580 and the second mechanical arm 582 can be disposed in one buffer chamber to move into or out of the reacting chamber 52.

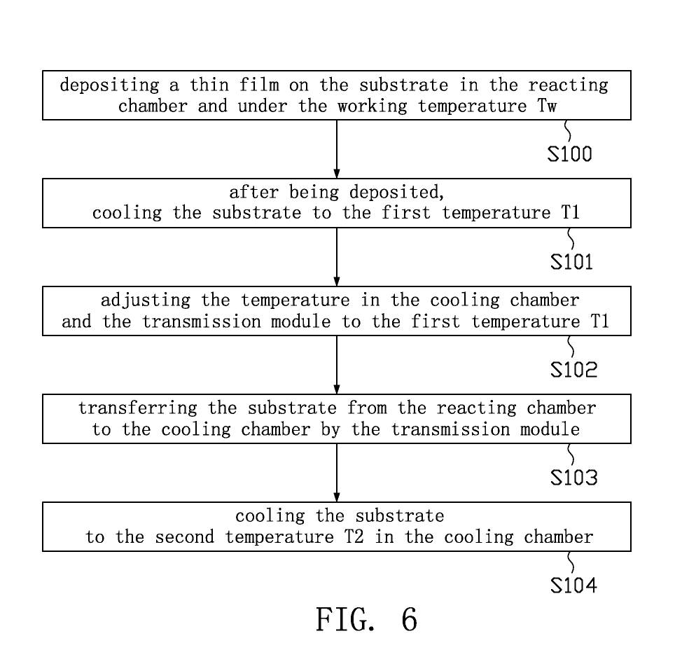

In addition, the present invention also provides a method for using the thin film deposition apparatus described above. Referring to FIG. 6, a flow chart is presented, which describes a method for using the apparatus in the first embodiment. The method includes: depositing a thin film on the substrate in the reacting chamber under the working temperature Tw (S100); after being deposited, cooling the substrate to the first temperature T1 (S101); adjusting the temperature in the cooling chamber and the transmission module to the first temperature T1 (S102); transferring the substrate from the reacting chamber to the cooling chamber by the transmission module (S 103); and cooling the substrate to the second temperature T2 in the cooling chamber (S104).

Referring to FIGS. 1 and 6, first, as in the step S100, the substrate 20 is deposited in the reacting chamber 12 under the working temperature Tw, for example, III-Nitride is deposited on the substrate 20. As in step S101, after being deposited, the substrate 20 is cooled to the first temperature T1. Then, as in step S102, the temperature in the cooling chamber 16 and the transmission module 18 is adjusted to the first temperature T1. And then, as in step S103, the substrate 20 being deposited is transferred from the reacting chamber 12 to the cooling chamber 16 by the transmission module 18. And as in step S104, the substrate 20 being deposited is cooled to the second temperature T2. The second temperature T2 is lower than the first temperature T1 but higher than the room temperature T0, i.e., T0 T2 T1 Tw. The first temperature T1 is in a range from 400 to 600, 500 for example. The second temperature T2 is in a range from the room temperature to 150, 100 for example.

To be specific, before step S100, the using method further includes the step of before being deposited, preheating the substrate to the first temperature T1 in the preheating chamber 14; adjusting the temperature of the transmission module 18 and the reacting chamber 12 to the first temperature T1; and transferring the substrate from the preheating chamber 14 to the reacting chamber 12 by the transmission module 18. After the steps mentioned above, the steps S100 through S104 are repeated. To be more specific, when the substrate 20 is moved out from the preheating chamber 14 by the mechanical arm 23, the first gate 24 is open, the second gate 26 and the third gate 28 are closed. The buffer chamber 22 is heated to a temperature same as the temperature of the preheating chamber 14. After the temperature of the reacting chamber 12 has being cooled to the first temperature T1, the second gate 26 is open, and the substrate 20 is transferred to the reacting chamber 12 by the mechanical arm 23. Now, the preheating chamber 22, the transmission module 18, and the reacting chamber 12 have the same gas atmosphere. When the substrate 20 is moved out from the reacting chamber 12 by the mechanical arm 23, the second gate 26 is open, and the first gate 24 and the third gate 28 are closed. The temperature in the buffer chamber 22 is same as the temperature in the reacting chamber 12. When the temperature in the cooling chamber 16 is up to the first temperature T1, the third gate 28 is open, and the substrate 20 is transferred to the cooling chamber 16 by the mechanical arm 23. Now, the cooling chamber 16, the transmission module 18 and the reacting chamber 12 have the same gas atmosphere. It can be understood that, the cooling chamber 16 and the preheating chamber 14 can be heated to the first temperature T1 at the same time.

In step S101, the method of cooling the substrate 20 to the first temperature includes supplying gas into the reacting chamber 12 by the gas supply equipment 29, wherein the gas includes hydrogen, nitrogen, or inert gas. The gas also can be supplied to the cooling chamber 16 and the preheating chamber 14 to accelerate cooling speed.

The method can further include a step of transferring another substrate being preheated to the first temperature T1 in the preheating chamber 14 to the reacting chamber 12 when the substrate 20 being deposited is transferred from the reacting chamber 12 to the cooling chamber 16 to save time.

In summary, in the present invention, when the thin film deposition process in the reacting chamber 12 is completed, the substrate 20 can be moved out from the reacting chamber 12 and put into the cooling chamber 16, not having to wait for the temperature of the reacting chamber to be cooled to a low temperature. During the period of cooling the substrate 20 in the cooling chamber 16, another substrate being preheated to the first temperature T1 in the preheating chamber 14 can be transferred to the reacting chamber 12 and deposited therein. Therefore, the interval time between deposition processes for each substrate can be saved, work efficiency can be improved, and energy also can be saved.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

1. A thin film deposition apparatus, for depositing a thin film on a substrate, the thin film deposition apparatus comprising:
a preheating chamber configured for preheating the substrate;
a reacting chamber, configured for receiving the substrate being preheated and transferred from the preheating chamber, heating the substrate to a working temperature, depositing a thin film on the substrate under the working temperature, and cooling the substrate being deposited to a temperature lower than the working temperature;
a cooling chamber, configured for receiving the substrate being deposited and transferred from the reacting chamber and further cooling the substrate; and
at least one transmission module, configured for transferring the substrate between the preheating chamber, the reacting chamber and the cooling chamber.

2. The apparatus as claimed in claim 1, wherein the at least one transmission module comprises a buffer chamber, the buffer chamber is connected to the preheating chamber, the reacting chamber, and the cooling chamber, respectively, by a gate, the buffer chamber comprising at least one mechanical arm disposed therein, the mechanical arm being configured for transferring the substrate between the preheating chamber and the reacting chamber before the substrate is deposited, and transferring the substrate between the reacting chamber and the cooling chamber after the substrate has been deposited.

3. The apparatus as claimed in claim 2, further comprising gas supply equipment, the gas supply equipment being connected to the preheating chamber, the buffer chamber, and the cooling chamber to supply at least one kind of inert gas to the preheating chamber, the buffer chamber, and the cooling chamber.

4. The apparatus as claimed in claim 3, wherein the buffer chamber and any of the other chambers connected thereto maintain the same gas atmosphere when the gate connected therebetween is open.

5. The apparatus as claimed in claim 2, wherein the preheating chamber, the buffer chamber and the cooling chamber each has at least one independent heater.

6. The apparatus as claimed in claim 5, wherein the buffer chamber and any of the other chambers connected thereto maintain the same temperature when the gate connected therebetween is open.

7. The apparatus as claimed in claim 1, wherein the transmission module comprises:
a first buffer chamber connected to the preheating chamber and the reacting chamber, respectively, by a gate, the first buffer chamber comprising a mechanical arm disposed therein that is configured for transferring the substrate between the preheating chamber and the reacting chamber before the substrate is deposited; and
a second buffer chamber connected to the reacting chamber and the cooling chamber, respectively, by a gate, the second buffer chamber comprising a second mechanical arm disposed therein and configured for transferring the substrate between the reacting chamber and the cooling chamber after the substrate has been deposited.

8. The apparatus as claimed in claim 7, further comprising gas supply equipment, the gas supply equipment being connected to the preheating chamber, the first buffer chamber, the second buffer chamber, and the cooling chamber to supply at least one kind of inert gas to the preheating chamber, the buffer chamber, the second buffer chamber, and the cooling chamber.

9. The apparatus as claimed in claim 8, wherein the first buffer chamber and the chambers connected thereto maintain the same gas atmosphere when the gate connected therebetween is open, and the second buffer chamber and the chambers connected thereto maintain the same gas atmosphere when the gate connected therebetween is open.

10. The apparatus as claimed in claim 7, wherein the first buffer chamber and the chambers connected thereto maintain the same temperature when the gate connected therebetween is open, and the second buffer chamber and the chambers connected thereto maintain the same temperature when the gate connected therebetween is open.

11. The apparatus as claimed in claim 1, wherein the preheating chamber and the cooling chamber are parallel set or stacked.

12. The apparatus as claimed in claim 1, wherein the thin film deposition apparatus is a metal-organic chemical vapor deposition apparatus that performs a metal-organic chemical vapor deposition process.

13. A thin film deposition apparatus, for depositing a thin film on a substrate, the thin film deposition apparatus comprising:
a preheating chamber configured for preheating the substrate to a first temperature;
a reacting chamber, configured for receiving the substrate being preheated and transferred from the preheating chamber, heating the substrate to a working temperature, depositing a thin film on the substrate under the working temperature, and cooling the substrate that has been deposited in the reacting chamber from the working temperature to the first temperature;
a cooling chamber, configured for receiving the substrate being deposited and transferred from the reacting chamber and further cooling the substrate from the first temperature to a second temperature; and
at least one transmission module, configured for transferring the substrate between the preheating chamber, the reacting chamber and the cooling chamber.

14. The apparatus as claimed in claim 13, wherein the first temperature is from 400° C. to 600° C.

15. The apparatus as claimed in claim 13, wherein the second temperature is from room temperature to 150° C.

16. A method for using a thin film deposition apparatus, comprising steps of:
depositing a thin film on the substrate in the reacting chamber and under a working temperature;
after being deposited, cooling the substrate to the first temperature;
adjusting the temperature in the cooling chamber and the transmission module to the first temperature;
transferring the substrate from the reacting chamber to the cooling chamber by the transmission module; and
cooling the substrate to the second temperature in the cooling chamber.

17. The method as claimed in claim 16, before depositing a thin film on the substrate in the reacting chamber, further comprising steps of:
preheating the substrate to the first temperature in a preheating chamber before the substrate being deposited;
adjusting the temperature of the transmission module and the reacting chamber to the first temperature; and
transferring the substrate from the preheating chamber to the reacting chamber by the transmission module.

18. The method as claimed in claim 17, further comprising repeating the steps in claim 17 after all steps in claim 18 being completed.

19. The method as claimed in claim 16, wherein the first temperature is from 400° C. to 600° C.

20. The method as claimed in claim 16, wherein the second temperature is from room temperature to 150° C.

21. The method as claimed in claim 16, before the step of transferring the substrate from the reacting chamber to the cooling chamber by the transmission module, further comprising a step of adjusting the cooling chamber, the transmission module, and the reacting chamber to the same gas atmosphere.

22. The method as claimed in claim 17, before the step of transferring the substrate from the preheating chamber to the reacting chamber cooling chamber by the transmission module, further comprising a step of adjusting the preheating chamber, the transmission module, and the reacting chamber to the same gas atmosphere.
